(19) United States
(12) Patent Application Publication
(10) Pub. No.: US 2022/0315823 A1
(43) Pub. Date: Oct. 6, 2022

(54) DIELECTRIC LAYER WITH IMPROVED THERMALLY CONDUCTIVITY

(71) Applicant: Rogers Corporation, Chandler, AZ (US)

(72) Inventors: Rebecca Lynn Agapov, Bear, DE (US); Matthew Raymond Himes, Newark, DE (US)

(21) Appl. No.: 17/840,911

(22) Filed: Jun. 15, 2022

Related U.S. Application Data
(63) Continuation of application No. 16/181,415, filed on Nov. 6, 2018, now abandoned.
(60) Provisional application No. 62/582,621, filed on Nov. 7, 2017.

(51) Int. Cl. C09K 5/14; C08K 3/22; C08K 3/36; C08J 5/00; C08F 14/26; C08K 9/00; H05K 1/03; H05K 3/00; H05K 1/02; C08K 3/38; H01B 3/44; H01L 23/14; H01L 23/373; C08L 27/20; C08L 27/16; C08J 5/04; C08L 27/14; C08J 5/10

(52) U.S. Cl. CPC C09K 5/14; C08K 3/22; C08K 3/36; C08J 5/005; C08F 14/26; C08K 9/00; H05K 1/0366; H05K 3/0014; H05K 1/0201; C08K 3/38; H01B 3/445; H01L 23/145; H01L 23/3735; C08L 27/20; C08L 27/16; C08J 5/043; C08L 27/14; H05K 1/0373; C08J 5/10; B29L 2031/3425

(57) ABSTRACT

In an embodiment the dielectric layer comprises a fluoropolymer, a plurality of boron nitride particles, a plurality of titanium dioxide particles, a plurality of silica particles; and a reinforcing layer. The dielectric layer can comprise at least one of 20 to 45 volume percent of the fluoropolymer, 15 to 35 volume percent of the plurality of boron nitride particles, 1 to 32 volume percent of the plurality of titanium dioxide particles, 10 to 35 volume percent of the plurality of silica particles, and 5 to 15 volume percent of the reinforcing layer; wherein the volume percent values are based on a total volume of the dielectric layer.

### CROSS-REFERENCE TO TECHNICALLY RELATED APPLICATION

This application is a Continuation of Non Provisional application Ser. No. 16/181,415 filed on Nov. 6, 2018 which claims the benefit of U.S. Provisional Patent Application Ser. No. 62/582,621 filed Nov. 7, 2017. The related applications are incorporated herein in their entirety by reference.

### BACKGROUND

Circuit subassemblies are used in the manufacture of single-layer circuits and multilayer circuits, and include, for example, circuit laminates, bond plies, resin-coated conductive layers, and cover films, as well as packaging substrate laminates and build-up materials. Each of the foregoing subassemblies contains a layer of a dielectric material. As electronic devices and the features thereon become smaller, thermal management of the resulting dense circuit layouts becomes increasingly important. A number of efforts have been made to improve the thermal conductivity of the circuit laminates by incorporating thermally conductive particulate fillers in the dielectric layer. Although adding large amounts of thermally conductive particulate fillers has been shown to increase the thermal conductivity, increased amounts of thermally conductive particulate fillers can adversely affect one or more of the mechanical properties of the dielectric layer.

Accordingly, there remains a need in the art for improving thermal conductivity of the circuit laminates without suffering unacceptable tradeoffs in other properties.

### BRIEF SUMMARY

Disclosed herein is a thermally conductive dielectric layer comprising a fluoropolymer and a dielectric filler composition.

In an embodiment, a dielectric layer comprises 25 to 45 volume percent of a fluoropolymer; 15 to 35 volume percent of a plurality of boron nitride particles; 1 to 32 volume percent of a plurality of titanium dioxide particles; 0 to 35 volume percent of a plurality of silica particles; and 5 to 15 volume percent of a reinforcing layer; wherein the volume percent values are based on a total volume of the dielectric layer.

Also disclosed herein is a method of making the dielectric layer comprising forming a mixture comprising a fluoropolymer, a plurality of boron nitride particles, a plurality of titanium dioxide particles, a plurality of silica particles, and a plurality of glass fibers; and forming the dielectric layer from the mixture; wherein the dielectric layer comprises 25 to 45 volume percent of a fluoropolymer; 15 to 35 volume percent of a plurality of boron nitride particles; 1 to 32 volume percent of a plurality of titanium dioxide particles; 0 to 35 volume percent of a plurality of silica particles; and 5 to 15 volume percent of a reinforcing layer; wherein the volume percent values are based on a total volume of the dielectric layer.

A further method of making the dielectric layer comprises impregnating the reinforcing layer with a mixture comprising the fluoropolymer, the plurality of boron nitride particles, the plurality of titanium dioxide particles, and the plurality of silica particles to form the dielectric layer; wherein the dielectric layer comprises 25 to 45 volume percent of a fluoropolymer; 15 to 35 volume percent of a plurality of boron nitride particles; 1 to 32 volume percent of a plurality of titanium dioxide particles; 0 to 35 volume percent of a plurality of silica particles; and 5 to 15 volume percent of a reinforcing layer; wherein the volume percent values are based on a total volume of the dielectric layer.

Further disclosed herein is an article comprising the dielectric layer; wherein the dielectric layer comprises 25 to 45 volume percent of a fluoropolymer; 15 to 35 volume percent of a plurality of boron nitride particles; 1 to 32 volume percent of a plurality of titanium dioxide particles; 0 to 35 volume percent of a plurality of silica particles; and 5 to 15 volume percent of a reinforcing layer; wherein the volume percent values are based on a total volume of the dielectric layer. The article can be a multilayer circuit board comprising the dielectric layer.

The above described and other features are exemplified by the following figures, detailed description, and claims.

### BRIEF DESCRIPTION OF THE DRAWINGS

Referring to the exemplary non-limiting drawings wherein like elements are numbered alike in the accompanying Figures:

FIG. 1 depicts an embodiment of a cross-sectional view of a dielectric layer;

FIG. 2 depicts an embodiment of a cross-sectional view of a single clad circuit material comprising the dielectric layer of FIG. 1;

FIG. 3 depicts an embodiment of a cross-sectional view of a double clad circuit material comprising the dielectric layer of FIG. 1;

FIG. 4 depicts an embodiment of a cross-sectional view of the metal clad circuit laminate of FIG. 3 with a patterned patch.

### DETAILED DESCRIPTION

Boron nitride is a high thermal conductivity ceramic filler often used in dielectric layers for circuit materials to increase their thermal conductivity and to help with thermal management. While the incorporation of boron nitride in dielectric layers can result in an increase in the thermal conductivity, increasing amounts of boron nitride can result in a decrease in the mechanical properties. For example, depending on the particle size distribution, the surface area, and surface chemistry of the filler, loadings of greater than or equal to 50 volume percent can exceed a maximum packing ratio of the powder in the material, such that adding additional powder can result in an increased number of voids becoming entrained in the material, and the material becoming brittle. The peel strength of copper foil bonded to the dielectric layer is an additional example of a mechanical property that can be affected by high loadings of boron nitride because the volume composition of boron nitride necessary to achieve high thermal conductivity often causes surface segregation of the filler material. This surface segregation can substantially reduce the copper foil peel strength to values below industrial specifications. A unique filler composition comprising a plurality of boron nitride particles; a plurality of titanium dioxide particles having a titanium dioxide D₅₀ value of 1 to 25 micrometers; and a plurality of silica particles was discovered that enables for a reduced amount of boron nitride particles while maintaining a high thermal conductivity. For example, the filler composition can comprise 15 to 35 volume percent of a plurality of boron nitride particles; 1 to 32 volume percent of a plurality of titanium dioxide particles having a titanium dioxide D₅₀ value of 1 to 25 micrometers; and 0 to 35 volume percent of a plurality of silica particles. As used herein, the particle size is measured by dynamic light scattering. Specifically, the unique size and amount of the plurality of titanium dioxide particles enables a reduced amount of boron nitride, resulting in the improved thermal properties of the dielectric layer. The ability of the filler composition to achieve such a high thermal conductivity is surprising as replacing an amount of the boron nitride with the titanium dioxide was expected to result in a decrease of the thermal conductivity.

More surprisingly, this high thermal conductivity was observed in a reinforced dielectric layer, where, reinforcing layers generally result in a decrease in the thermal conductivity of the dielectric layer. Specifically, the present dielectric layer can achieve a z-direction relative z-direction thermal conductivity of greater than or equal to 0.8 as determined in accordance with ASTM D5470-12 relative to the dielectric layer of Example 1. The ability to achieve a high thermal conductivity with a reinforcing layer results in an improvement in the mechanical properties of the dielectric layer, enabling flexural strength not achieved without the reinforcing layer.

The dielectric layer comprises a fluoropolymer. “Fluoropolymers” as used herein, include homopolymers and copolymers that comprise repeat units derived from a fluorinated alpha-olefin monomer, i.e., an alpha-olefin monomer that includes at least one fluorine atom substituent, and optionally, a non-fluorinated, ethylenically unsaturated monomer reactive with the fluorinated alpha-olefin monomer. Exemplary fluorinated alpha-olefin monomers include CF₂═CF₂, CHF═CF₂, CH₂═CF₂, CHCl═CHF, CClF═CF₂, CCl₂═CF₂, CC1F═CC1F, CHF═CC1₂, CH₂═CC1F, CC1₂=CC1F, CF₃CF═CF₂, CF₃CF═CHF, CF₃CH═CF₂, CF₃CH═CH₂, CHF₂CH═CHF, CF₃CF═CF₂, and perfluoro(C₂₋₈ alkyl)vinylethers such as perfluoromethyl vinyl ether, perfluoropropyl vinyl ether, and perfluorooctylvinyl ether. The fluorinated alpha-olefin monomer can comprise tetrafluoroethylene (CF₂═CF₂), chlorotrifluoroethylene (CC1F═CF₂), (perfluorobutyl)ethylene, vinylidene fluoride (CH₂═CF₂), hexafluoropropylene (CF₂═CFCF₃), or a combination comprising at least one of the foregoing. Exemplary non-fluorinated monoethylenically unsaturated monomers include ethylene, propylene, butene, and ethylenically unsaturated aromatic monomers such as styrene and alpha-methyl-styrene. Exemplary fluoropolymers include poly(chlorotrifluoroethylene) (PCTFE), poly(chlorotrifluoroethylene-propylene), poly(ethylene-tetrafluoroethylene) (ETFE), poly(ethylene-chlorotrifluoroethylene) (ECTFE), poly(hexafluoropropylene), poly(tetrafluoroethylene) (PTFE), poly(tetrafluoroethylene-ethylene-propylene), poly(tetrafluoroethylene-hexafluoropropylene) (also known as fluorinated ethylene-propylene copolymer (FEP)), poly(tetrafluoroethylene-propylene) (also known as fluoroelastomer (FEPM), poly(tetrafluoroethylene-perfluoropropylene vinyl ether), a copolymer having a tetrafluoroethylene backbone with a fully fluorinated alkoxy side chain (also known as a perfluoroalkoxy polymer (PFA)) (for example, poly(tetrafluoroethylene-perfluoroproplyene vinyl ether)), polyvinylfluoride (PVF), polyvinylidene fluoride (PVDF), poly(vinylidene fluoride-chlorotrifluoroethylene), perfluoropolyether, perfluorosulfonic acid, and perfluoropolyoxetane, or a combination comprising at least one of the foregoing. The fluoropolymer can comprise at least one of a perfluoroalkoxy alkane polymer or a fluorinated ethylene-propylene. The fluoropolymer can comprise a perfluoroalkoxy alkane polymer. A combination comprising at least one of the foregoing fluoropolymers can be used.

In some embodiments the fluoropolymer is at least one of FEP, PFA, ETFE, or PTFE, which can be fibril forming or non-fibril forming. FEP is available under the trade name TEFLON FEP from DuPont or NEOFLON FEP from Daikin; and PFA is available under the trade name NEOFLON PFA from Daikin, TEFLON PFA from DuPont, or HYFLON PFA from Solvay Solexis.

The fluoropolymer can comprise PTFE. The PTFE can comprise a PTFE homopolymer, a trace modified PTFE homopolymer, or a combination comprising one or both of the foregoing. As used herein, a trace modified PTFE homopolymer comprises less than 1 wt % of a repeat unit derived from a co-monomer other than tetrafluoroethylene based on the total weight of the polymer.

The fluoropolymer can be rendered crosslinkable by the inclusion of crosslinkable monomers into the backbone of the fluoropolymer, which includes the terminal ends of the fluoropolymer. The crosslinkable monomer can be crosslinked by any thermally, chemically, or photoinitiated cross-linking technologies known to those skilled in the art, depending upon the resulting properties desired. An exemplary crosslinkable fluoropolymer is a (meth)acrylate fluoropolymer that comprises (meth)acrylate functionalities, which includes both acrylates and methacrylates. For example, the crosslinkable fluoropolymer can have the formula:

H₂C═CR′COO—(CH₂)ₙ—R—(CH₂)ₙ—OOCR′═CH₂

wherein R is an oligomer of a fluorinated alpha-olefin monomer or non-fluorinated monoethylenically unsaturated monomer as described above, R′ is H or —CH₃, and n is 1 to 4. R can be an oligomer comprising units derived from tetrafluoroethylene.

The crosslinked fluoropolymer network can be made by exposing the (meth)acrylate fluoropolymer to a source of free radicals in order to initiate a radical crosslinking reaction through the acrylate groups on the fluoropolymer. The source of the free radicals can be an ultraviolet (UV) light sensitive radical initiator or the thermal decomposition of an organic peroxide. Suitable photoinitiators and organic peroxides are well known in the art. Crosslinkable fluoropolymers are commercially available, for example, VITON B from the DuPont Company.

The dielectric layer can comprise 20 to 45 volume percent, or 35 to 45 volume percent of the fluoropolymer based on a total volume of the dielectric layer.

The dielectric layer comprises a filler composition comprising boron nitride, titanium dioxide, and silica. The filler composition can comprise boron nitride, rutile titanium dioxide, and silica. The filler composition can comprise rutile titanium dioxide and amorphous silica, having a high and low dielectric constant, respectively, as this combination can permit a broad range of dielectric constants combined with a low dissipation factor in the dielectric layer by adjusting their respective amounts.

The dielectric layer comprises a plurality of boron nitride particles (also referred to herein as boron nitride). The boron nitride particles can be crystalline, polycrystalline, amorphous, or a combination thereof. The boron nitride particles can be in the form of platelets (for example, hexagonal platelets). The boron nitride particles can have a D₅₀ particle size of 5 to 40 micrometers, 10 to 25 micrometers, or 12 to 20 micrometers, or 15 to 20 micrometers. As used herein, the D₅₀ particle size corresponds 50% by number of the particles being larger than the D₅₀ value and 50% by number of the particles being smaller than the D₅₀ value as measured by laser light scattering. As applied to the boron nitride platelets, the D₅₀ value can refer to the maximum lateral dimension. The boron nitride platelets can have a thickness 1 to 5 micrometers, or 1 to 2 micrometers. A ratio of the lateral dimension to the thickness can be greater than or equal to 5, or greater than or equal to 10. The boron nitride particles can have an average surface area of 0.5 to 20 meters squared per gram (m²/g), or 1 to 15 m²/g.

The filler composition can optionally further comprise boron nitride fibers, boron nitride tubes, spherical boron nitride particles, ovoid boron nitride particles, irregularly shaped boron nitride particles, or a combination comprising at least one of the foregoing. The boron nitride fibers and tubes can have one or both of an average outer diameter of 10 nm to 10 micrometers and a length of greater than or equal to 1 micrometer, or 10 micrometers to 10 centimeters (cm), or 500 micrometers to 1 mm. The boron nitride fibers or tubes can have an aspect ratio, calculated as a length/cross-sectional dimension of 10 to 1,000,000, or 20 to 500,000, or 40 to 250,000.

The boron nitride can have a thermal conductivity of 100 to 2,000 watts per meter Kelvin (W/m·K), or 100 to 1,800 W/m·K, or 100 to 1,600 W/m·K. A method of determining the thermal conductivity is in accordance with ASTM E1225-13.

The dielectric layer can comprise 15 to 35 volume percent, or 15 to 30 volume percent, or 18 to 30 volume percent, or 20 to 25 volume percent of boron nitride particles based on the total volume of the dielectric layer. If the dielectric layer comprises too little boron nitride then the desired thermal conductivity may not be achieved and if the dielectric layer comprises too much boron nitride then a decrease in the mechanical properties may be observed.

The boron nitride particles can form agglomerates in the dielectric layer. The agglomerates can have an average agglomerate size distribution (ASD), or diameter, of 1 to 200 micrometers, or 2 to 125 micrometers, or 3 to 40 micrometers. The boron nitride can be present as a mixture of agglomerates and/or non-agglomerated boron nitride particles. In particular, 50 volume percent or less, 30 volume percent or less, or 10 volume percent or less of the boron nitride can be agglomerated in the dielectric layer, as determined from transmission electron micrographs of the dielectric layer.

The dielectric layer comprises a plurality of titanium dioxide particles (also referred to herein as titanium dioxide). The titanium dioxide can comprise rutile titanium dioxide, anatase titanium dioxide, or a combination comprising at least one of the foregoing. The titanium dioxide can comprise rutile titanium dioxide. The titanium dioxide particles can have a D₅₀ particle size by of 1 to 40 micrometers, or 5 to 40 micrometers, 1 to 25 micrometers, or 1 to 20 micrometers. The titanium dioxide particles can be irregular having a plurality of flat surfaces.

The dielectric layer can comprise 0 to 40 volume percent, 1 to 35 volume percent, or 1 to 32 volume percent, or 1 to 10 volume percent of titanium dioxide particles based on the total volume of the dielectric layer.

The dielectric layer can comprise a plurality of silica particles (also referred to herein as silica). The silica particles can comprise micro-crystalline silica, amorphous silica (for example, fused amorphous silica), or a combination comprising at least one of the foregoing. The silica particles can be spherical or irregular. The silica particles can have a D₅₀ particle size of 5 to 15 micrometers, or 5 to 10 micrometers. The small particle size of the silica particles can result in good dielectric properties even with the incorporation of the reinforcing layer.

The dielectric layer can comprise 0 to 35 volume percent, or 0 to 25 volume percent, or 15 to 30 volume percent of silica particles based on the total volume of the dielectric layer.

The filler composition can further comprise calcium titanate, barium titanate, strontium titanate, glass beads, or a combination comprising at least one of the foregoing. The filler composition can further comprise SrTiO₃, CaTiO₃, BaTiO₄, Ba₂Ti₉O₂₀, or a combination comprising at least one of the foregoing.

A volume ratio of the boron nitride to the silica can be 1:0 to 1:2, or 1:0 to 1:1.5, or 1:0.5 to 1:1.5, or 1:0.8 to 1:1.4. A ratio of the D₅₀ value of the boron nitride to the D₅₀ value of the silica can be 1:0.25 to 1:1.25, or 1:0.3 to 1:1.1, or 1:0.25 to 1:0.75, or 1:0.4 to 1:0.6. A volume ratio of the boron nitride to the titanium dioxide can be 1:0.01 to 1:1.7, or 1:0.2 to 1:1.5. A volume ratio of the boron nitride to the titanium dioxide can be 1:0.1 to 1:0.6, or 1:0.2 to 1:0.4. A ratio of the D₅₀ value of the boron nitride to the D₅₀ value of the titanium dioxide can be 1:0.1 to 1:2.5, or 1:0.1 to 1:2. A ratio of the D₅₀ value of the boron nitride to the D₅₀ value of the titanium dioxide can be 1:0.8 to 1:1.2

One or more of the boron nitride particles, the titanium dioxide particles, and the silica particles can be surface-treated to aid dispersion into the fluoropolymer, for example, with a surfactant, a silane, an organic polymer, or other inorganic material. For example, the particles can be coated with a surfactant such as oleylamine oleic acid, or the like. The silane can comprise N-β(aminoethyl)-γ-aminopropyltriethoxysilane, N-β(aminoethyl)-γ-aminopropyltrimethoxysilane, γ-aminopropyltriethoxysilane, γ-aminopropyltrimethoxysilane, 3-chloropropyl-methoxysilane, γ-glycidoxypropyltriethoxysilane, γ-glycidoxypropyltrimethoxysilane, γ-mercaptopropyltriethoxysilane, γ-mercaptopropyltrimethoxysilane, γ-methacryloxypropyltriethoxysilane, γ-methacryloxypropyltrimethoxysilane, N-phenyl-γ-aminopropyltriethoxysilane, N-phenyl-γ-aminopropyltrimethoxysilane, phenyl silane, trichloro(phenyl)silane, 3-(triethoxysilyl)propyl succinyl anhydride, tris(trimethylsiloxy)phenyl silane, vinylbenzylaminoethylaminopropyltrimethoxysilane, vinyl-trichlorosilane, vinyltriethoxysilane, vinyltrimethoxysilane, vinyltris(betamethoxyethoxy)silane, or a combination comprising at least one of the foregoing. The silane can comprise phenyl silane. The silane can comprise a substituted phenyl silane, for example, those described in U.S. Pat. No. 4,756,971. The silane can be present at 0.01 to 2 wt %, or 0.1 to 1 wt %, based on the total weight of the coated particles. The particles can be coated with SiO₂, Al₂O₃, MgO, silver, or a combination comprising one or more of the foregoing. The particles can be coated by a base-catalyzed sol-gel technique, a polyetherimide (PEI) wet and dry coating technique, or a poly(ether ether ketone) (PEEK) wet and dry coating technique.

The boron nitride particles can comprise a surface coating comprising a ceramic, a metal oxide, a metal hydroxide, or a combination comprising at least one of the foregoing. The surface coating can comprise silica, alumina, boehmite, magnesium hydroxide, titania, silicon carbide, silicon oxycarbide, or a combination comprising at least one of the foregoing. The surface coating can be derived from a polysilazane, a polycarbosilane, a siloxane, a polysiloxane, a polycarbosiloxane, a silsesquioxane, a polysilsesquioxane, a polycarbosilazane, or a combination comprising at least one of the foregoing.

The dielectric layer comprises a reinforcing layer comprising a plurality of fibers that can help control shrinkage within the plane of the dielectric layer during cure and can provide an increased mechanical strength relative to the same dielectric layer without the reinforcing layer. The reinforcing layer can be a woven layer or a non-woven layer. The fibers can comprise glass fibers (such as E glass fibers, S glass fibers, and D glass fibers), silica fibers, polymer fibers (such as polyetherimide fibers, polysulfone fibers, poly(ether ketone) fibers, polyester fibers, polyethersulfone fibers, polycarbonate fibers, aromatic polyamide fibers, liquid crystal polymer fibers such as VECTRAN commercially available from Kuraray)), or a combination comprising at least one of the foregoing. The fibers can have a diameter of 10 nanometers to 10 micrometers. The reinforcing layer can have a thickness of less than or equal to 200 micrometers, or 50 to 150 micrometers. The dielectric layer can comprise 5 to 15 volume percent, or 6 to 10 volume percent, or 7 to 11 volume percent, or 7 to 9 volume percent of the reinforcing layer.

The thickness of the dielectric layer will depend on its intended use. The thickness of the dielectric layer can be 5 to 1,000 micrometers, or 5 to 500 micrometers, or 5 to 400 micrometers. In another embodiment, when used as a dielectric substrate layer, the thickness of the composite is 250 to 4,000 micrometers, or 500 micrometers to 2,000 micrometers, or 500 micrometers to 1,000 micrometers.

The dielectric layer can have a permittivity of greater than or equal to 2, or 2 to 6.5, or 2 to 5 as measured at a frequency of 10 gigahertz (GHz). The dielectric layer can have a dissipation factor of less than or equal to 0.003 as measured at a frequency of 10 GHz. The permittivity (Dk) and the dielectric loss or dissipation factor (Df) can be measured in accordance “Stripline Test for Permittivity and Loss Tangent at X-Band” test method IPC-TM-650 2.5.5.5 at a temperature of 23 to 25° C.

The dielectric layer can have a z-direction thermal conductivity of 0.5 to 10 W/m·K, or 0.5 to 5 W/m·K, or 1 to 2 W/m·K. The “z-direction thermal conductivity” refers to thermal conductivity in the direction perpendicular to the plane of the dielectric layer. The z-direction thermal conductivity can be measured in accordance with ASTM D5470-12.

The dielectric layer can be prepared by impregnating a reinforcing layer with a mixture comprising the fluoropolymer, the plurality of boron nitride particles, the plurality of titanium dioxide particles, the optional plurality of silica particles, and an optional solvent. The impregnating can comprise casting the mixture onto the reinforcing layer or dip-coating the reinforcing layer into the mixture, or roll-coating the mixture onto the reinforcing layer.

The dielectric layer can be prepared by forming a mixture comprising the filler composition and a plurality of glass fibers in water; adding the fluoropolymer in the form of a dispersion, for example, in water; and forming the dielectric layer. The forming can comprise paste extruding and calendering. The forming can comprise forming on a papermaking machine.

The mixture can be formed by mixing the fluoropolymer, the plurality of boron nitride particles, the plurality of titanium dioxide particles, the plurality of silica particles, and an optional solvent. The mixture can be formed by mixing a filler composition comprising the plurality of boron nitride particles, the plurality of titanium dioxide particles, the plurality of silica particles, and an optional filler composition solvent with a fluoropolymer composition comprising the fluoropolymer and an optional fluoropolymer composition solvent. The thickness of the dielectric layer can be controlled by metering the mixture to the correct thickness. After forming the reinforcing layer, any solvent can be removed.

The solvent can be present to adjust the viscosity of the mixture and can facilitate forming of the dielectric layer, for example, during impregnation of the reinforcing layer. The solvent can be selected so as to dissolve or disperse the fluoropolymer and the filler composition and to have a convenient evaporation rate for applying the mixture and drying the dielectric layer. A non-exclusive list of solvents and dispersing media includes an alcohol (such as methanol, ethanol, and propanol), cyclohexane, heptane, hexane, isophorone, methyl ethyl ketone, methyl isobutyl ketone, nonane, octane, toluene, water, xylene, and terpene-based solvents. For example, the solvent can comprise hexane, methyl ethyl ketone, methyl isobutyl ketone, toluene, xylene, or a combination comprising at least one of the foregoing. The solvent can comprise water. When the method of forming the dielectric substrate comprises forming a filler composition and a fluoropolymer composition, the filler composition solvent and the fluoropolymer composition solvent can be the same or different. For example, the fluoropolymer composition solvent can comprise water and the filler composition solvent can comprise an alcohol.

The mixture can comprise a viscosity modifier to retard separation, for example, by sedimentation or flotation, of the filler composition from the fluoropolymer and to provide the mixture with a viscosity compatible with forming the dielectric layer. Exemplary viscosity modifiers include polyacrylic acid, vegetable gums, and cellulose based compounds. Specific examples of viscosity modifiers include polyacrylic acid, methyl cellulose, polyethyleneoxide, guar gum, locust bean gum, sodium carboxymethylcellulose, sodium alginate, and gum tragacanth. Alternatively, the viscosity modifier can be omitted if the viscosity of the solvent is sufficient to provide a mixture that does not separate during the time period of interest.

After impregnating the reinforcing layer, the dielectric layer can be heated, for example, to remove any solvent or viscosity modifier or to sinter the fluoropolymer.

A laminate can be formed by forming a multilayer stack comprising one or more of the dielectric layers and one or more conductive layers; and laminating the multilayer stack. Adhesion layers can optionally be present in the multilayer stack to promote adhesion there between. The multilayer stack can be placed in a press, for example, a vacuum press, under a pressure and temperature for a duration of time suitable to bond the layers and form the laminate. Alternatively, the dielectric substrate can be free of a conductive layer, such as a copper foil.

A circuit material comprising the dielectric layer can be prepared by forming a multilayer material having the dielectric layer with a conductive layer disposed thereon. Useful conductive layers include, for example, stainless steel, copper, gold, silver, aluminum, zinc, tin, lead, transition metals, or alloys comprising at least one of the foregoing. There are no particular limitations regarding the thickness of the conductive layer, nor are there any limitations as to the shape, size, or texture of the surface of the conductive layer. The conductive layer can have a thickness of 3 to 200 micrometers, or 9 to 180 micrometers. When two or more conductive layers are present, the thickness of the two layers can be the same or different. The conductive layer can comprise a copper layer. Suitable conductive layers include a thin layer of a conductive metal such as a copper foil presently used in the formation of circuits, for example, electrodeposited copper foils. The copper foil can have a root mean squared (RMS) roughness of less than or equal to 2 micrometers, or less than or equal to 0.7 micrometers, where roughness is measured using a stylus profilometer.

The conductive layer can be applied by laminating the conductive layer and the dielectric layer, by direct laser structuring, or by adhering the conductive layer to the substrate via an adhesive layer. Other methods known in the art can be used to apply the conductive layer where permitted by the particular materials and form of the circuit material, for example, electrodeposition, chemical vapor deposition, and the like.

The laminating can entail laminating a multilayer stack comprising the dielectric layer, a conductive layer, and an optional intermediate layer between the dielectric layer and the conductive layer to form a layered structure. The conductive layer can be in direct contact with the dielectric layer, without the intermediate layer. The layered structure can then be placed in a press, e.g., a vacuum press, under a pressure and temperature for a duration of time suitable to bond the layers and form a laminate. Lamination and optional curing can be by a one-step process, for example, using a vacuum press, or can be by a multi-step process. In a one-step process, the layered structure can be placed in a press, brought up to laminating pressure (e.g., 150 to 1,200 pounds per square inch (psi)) (1.0 to 8.3 megapascal) and heated to laminating temperature (e.g., 260 to 390 degrees Celsius (° C.)). The laminating temperature and pressure can be maintained for a desired soak time, for example, 20 minutes, and thereafter cooled (while still under pressure) to less than or equal to 150° C.

If present, the intermediate layer can comprise a polyfluorocarbon film that can be located in between the conductive layer and the dielectric layer, and an optional layer of microglass reinforced fluorocarbon polymer can be located in between the polyfluorocarbon film and the conductive layer. The layer of microglass reinforced fluorocarbon polymer can increase the adhesion of the conductive layer to the substrate. The microglass can be present in an amount of 4 to 30 weight percent (wt %) based on the total weight of the layer. The microglass can have a longest length scale of less than or equal to 900 micrometers, or less than or equal to 500 micrometers. The microglass can be microglass of the type as commercially available by Johns-Manville Corporation of Denver, Colo. The polyfluorocarbon film comprises a fluoropolymer (such as polytetrafluoroethylene, a fluorinated ethylene-propylene copolymer, and a copolymer having a tetrafluoroethylene backbone with a fully fluorinated alkoxy side chain).

The conductive layer can be applied by laser direct structuring. Here, the dielectric layer can comprise a laser direct structuring additive; and the laser direct structuring can comprise using a laser to irradiate the surface of the substrate, forming a track of the laser direct structuring additive, and applying a conductive metal to the track. The laser direct structuring additive can comprise a metal oxide particle (such as titanium oxide and copper chromium oxide). The laser direct structuring additive can comprise a spinel-based inorganic metal oxide particle, such as spinel copper. The metal oxide particle can be coated, for example, with a composition comprising tin and antimony (for example, 50 to 99 wt % of tin and 1 to 50 wt % of antimony, based on the total weight of the coating). The laser direct structuring additive can comprise 2 to 20 parts of the additive based on 100 parts of the respective composition. The irradiating can be performed with a YAG laser having a wavelength of 1,064 nanometers under a output power of 10 Watts, a frequency of 80 kilohertz (kHz), and a rate of 3 meters per second. The conductive metal can be applied using a plating process in an electroless plating bath comprising, for example, copper.

The conductive layer can be applied by adhesively applying the conductive layer. The conductive layer can be a circuit (the metallized layer of another circuit), for example, a flex circuit. An adhesion layer can be disposed between one or more conductive layers and the substrate.

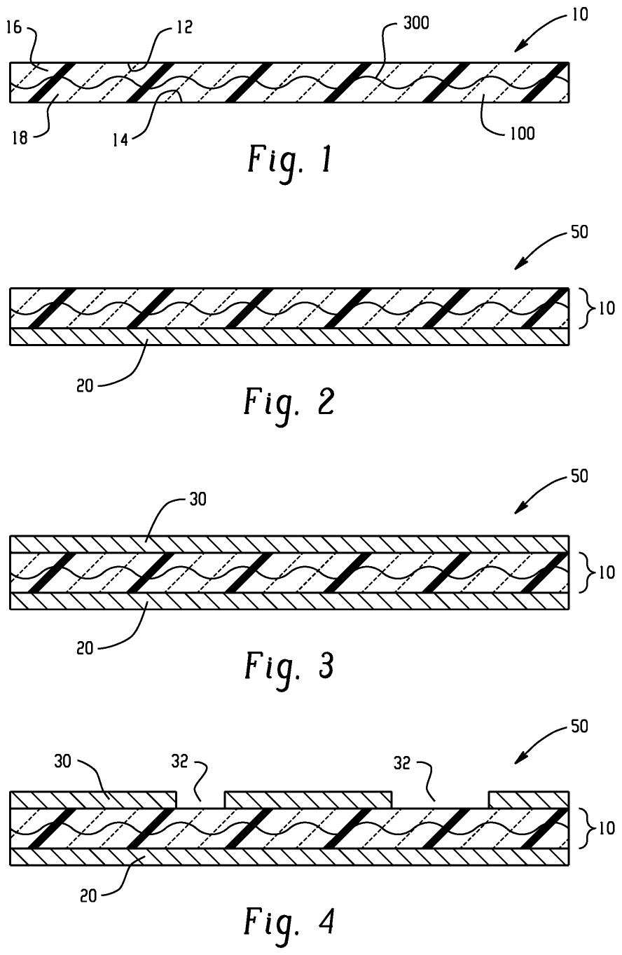

An exemplary dielectric layer is illustrated in FIG. 1. Dielectric layer 100 comprises the fluoropolymer, the filler composition, and reinforcing layer 300. Reinforcing layer 300 can be a woven layer or a non-woven layer. Dielectric layer 100 has a first planar surface 12 and a second planar surface 14. Dielectric layer 100 can have a first dielectric layer portion 16 located on a side of the reinforcing layer and a second dielectric layer portion 18 located on a second side of the reinforcing layer. As used herein, the terms “first dielectric” and “second dielectric” refer to the regions on each side of reinforcing layer 300, and do not limit the various embodiments to two separate portions.

While reinforcing layer 300 is depicted in FIGS. 1-4 by a wavy line having a “line-thickness”, it will be appreciated that such depiction is for general illustrative purposes and is not intended to limit the scope of the embodiments disclosed herein. Reinforcing layer 300 can be a woven or nonwoven fibrous material that allows contact between dielectric layer 100 through voids in reinforcing layer 300.

An exemplary circuit material comprising the dielectric layer 100 of FIG. 1 is shown in FIG. 2, wherein a conductive layer 20 is disposed on planar surface 14 of dielectric layer 100 to form a single clad circuit material 50. As used herein and throughout the disclosure, “disposed” means that the layers partially or wholly cover each other. An intervening layer, for example, an adhesive layer, can be present between conductive layer 20 and dielectric layer 100 (not shown).

Another exemplary embodiment is shown in FIG. 3, wherein a double clad circuit material 50 comprises dielectric layer 100 of FIG. 1 disposed between two conductive layers 20 and 30. One or both of conductive layers 20 and 30 can be in the form of a circuit (not shown) to form a double clad circuit. An adhesive (not shown) can be used on one or both sides of dielectric layer 100 to increase adhesion between the dielectric layer and the conductive layer(s). Additional layers can be added to result in a multilayer circuit.

FIG. 4 depicts double clad circuit material 50 having the conductive layer 30 patterned via etching, milling, or any other suitable method. As used herein, the term “patterned” includes an arrangement where the conductive element 30 has in-line and in-plane conductive discontinuities 32. The circuit material can further comprise a signal line, which can be a central signal conductor of a coaxial cable, a feeder strip, or a micro-strip, for example, can be disposed in signal communication with conductive element 30. A coaxial cable can be provided having a ground sheath disposed around the central signal line, the ground sheath can be disposed in electrical ground communication with conductive ground layer 20.

The dielectric layer can be used in a variety of circuit materials. As used herein, a circuit material is an article used in the manufacture of circuits and multilayer circuits, and includes, for example, circuit subassemblies, bond plies, resin-coated conductive layers, unclad dielectric layers, free films, and cover films. Circuit subassemblies include circuit laminates having a conductive layer, e.g., copper, fixedly attached to a dielectric layer. Double clad circuit laminates have two conductive layers, one on each side of the dielectric layer. Patterning a conductive layer of a laminate, for example, by etching, provides a circuit. Multilayer circuits comprise a plurality of conductive layers, at least one of which can contain a conductive wiring pattern. Typically, multilayer circuits are formed by laminating one or more circuits together using bond plies, by building up additional layers with resin coated conductive layers that are subsequently etched, or by building up additional layers by adding unclad dielectric layers followed by additive metallization. After forming the multilayer circuit, known hole-forming and plating technologies can be used to produce useful electrical pathways between conductive layers.

The dielectric layer can be used in an antenna. The antenna can be used in a mobile phone (such as a smart phone), a tablet, a laptop, or the like.

The following examples are provided to illustrate the present disclosure. The examples are merely illustrative and are not intended to limit devices made in accordance with the disclosure to the materials, conditions, or process parameters set forth therein.

### EXAMPLES

The materials used are listed in Table 1 were used in the following examples.

TABLE 1

| Component | Description | Supplier |
|---|---|---|
| Boron | Boron nitride having a D₅₀ value of 16 | Saint-Gobain |
| nitride-16 | micrometers, CARBOTHERM ™ PCTP16 | |
| Boron | Boron nitride having a D₅₀ value of 18 | Denka |
| nitride-18 | micrometers, SGP | |
| Boron | Boron nitride having a D₅₀ value of 8 | 3M ™ |
| nitride-8 | micrometers, CFP 009 | |
| Titanium | Non-spherical titanium dioxide having a | Ferro |
| dioxide-3 | D₅₀ value of 3 micrometers, TICON VCG | Electronic |
| | | Materials |
| Titanium | 100% rutile, fully densified, non-spherical | Rogers |
| dioxide-16 | titanium dioxide having a D₅₀ value of 16 | Corporation |
| | micrometers | |
| Silica-8 | Spherical silica having a D₅₀ value of 8 | Denka |
| | micrometers, FB8S | |
| Silica-9 | Non-spherical silica having a D₅₀ value of | Imerys |
| | 9 micrometers, TECO-SIL ™ 44i | Refractory |
| | | Minerals |
| Alumina-10 | Spherical alumina having a D₅₀ value of | Denka |
| | 10 micrometers, DAW-10 | |
| Fiberglass | Woven electronic grade fiberglass | JPS |
| | reinforcing layer, 0.7 to 2.9 ounces per | Composite |
| | square yard (OSY) (23.8 to 98.6 grams | Materials |
| | per square meter) | Corp. |
| PTFE | Teflon ™ Polytetrafluoroethylene, Disp 30 | Chemours ™ |

In the examples, the relative thermal conductivity was based on the z-direction thermal conductivity determined in accordance with ASTM D5470-12.

### Examples 1-11

Dielectric layers were prepared by impregnating a woven fiberglass reinforcing layer with polytetrafluoroethylene and the filler compositions as defined in Table 2, where all of the amounts are shown in volume percent and the relative TC refers to the z-direction thermal conductivity relative to Example 1.

TABLE 2

| Example | 1 | 2 | 3 | 4 | 5 | 6 | 7 | 8 | 9 | 10 | 11 |
|---|---|---|---|---|---|---|---|---|---|---|---|
| PTFE | 39.1 | 39.1 | 39.1 | 36.4 | 39.8 | 39.6 | 39.3 | 39.7 | 39.7 | 40.2 | 37.8 |
| Boron nitride-16 | 22.5 | 22.5 | 22.5 | 20.9 | 24.4 | 24.3 | 23.9 | — | — | — | 23.1 |
| Boron nitride-18 | — | — | — | — | — | — | — | — | — | 24.0 | — |
| Boron nitride-8 | — | — | — | — | — | — | — | 23.7 | 23.7 | — | — |
| Titanium dioxide-3 | — | 7.4 | — | — | — | — | — | 7.6 | — | — | — |
| Titanium dioxide-16 | 7.4 | — | 7.4 | 6.7 | 7.3 | 6.5 | — | — | 7.6 | 7.7 | 1.0 |
| Silica-8 | 21.1 | 21.1 | — | 19.7 | 20.3 | 21.6 | 24.6 | 20.1 | 20.1 | 20.3 | 30.3 |
| Silica-9 | — | — | 21.1 | — | — | — | — | — | — | — | — |
| Alumina-10 | — | — | — | — | — | — | 5.2 | — | — | — | — |
| Fiberglass | 9.9 | 9.9 | 9.9 | 16.2 | 8.0 | 8.0 | 7.0 | 8.9 | 8.9 | 7.9 | 7.8 |
| Relative TC | 1.0 | 0.8 | 0.9 | 0.7 | 1.0 | 1.0 | 0.7 | 1.0 | 1.0 | 1.0 | 0.8 |

Table 2 shows that changing the particle size of the titanium dioxide from a D50 value of 16 micrometers of Example 1 to a D50 value of 3 micrometers of Example 2 still provides 80% of the relative z-direction thermal conductivity.

Table 2 also shows that changing the silica particle morphology from spherical of Example 1 to non-spherical of Example 3, while maintaining particle size, did not strongly affect the thermal conductivity.

In Example 4, the volume percent of the fiberglass reinforcement was increased to 16.2 volume percent. Even though the ceramic components are the same size and morphology as Example 1, the increased volume of reinforcement decreases the relative thermal conductivity below 75% of that in Example 1.

In Example 5, the volume percent of the fiberglass reinforcement was decreased to 8.0 volume percent. This small change in the volume percent of the fiberglass reinforcement did not strongly affect the z-direction thermal conductivity.

In Example 6, small changes were made to the ratio of titanium dioxide and silica. These small changes can enable tuning the dielectric constant, but did not strongly affect the thermal conductivity.

In Example 7, the titanium dioxide was replaced with aluminum oxide. This change in material decreased the relative thermal conductivity below 75% of that in Example 1.

In Example 8 and Example 10, the size of the boron nitride was changed, while the particle geometry was maintained. The thermal conductivity was not strongly affected by this change.

In comparing Example 8 and Example 9, the size of titanium dioxide was changed, while the particle geometry was maintained. The thermal conductivity was not strongly affected by this change.

In Example 11, the amount of titanium dioxide was decreased to only 1.0 volume percent. While a decrease in relative z-direction thermal conductivity was observed, it was still within 80% of the value shown in Example 1.

Set forth below are various non-limiting aspects of the present disclosure.

Aspect 1: A dielectric layer comprising: a fluoropolymer, a plurality of boron nitride particles, a plurality of titanium dioxide particles, a plurality of silica particles, and a reinforcing layer. The dielectric layer can comprise at least one of 20 to 45 volume percent of the fluoropolymer; 15 to 35 volume percent of the plurality of boron nitride particles; 1 to 32 volume percent of the plurality of titanium dioxide particles; 0 to 35 volume percent of the plurality of silica particles; and 5 to 15 volume percent of the reinforcing layer; wherein the volume percent values are based on a total volume of the dielectric layer. The dielectric layer can comprise at least one of 20 to 45 volume percent of the fluoropolymer; 15 to 35 volume percent of the plurality of boron nitride particles; 5 to 20 volume percent of the plurality of titanium dioxide particles; 10 to 35 volume percent of the plurality of silica particles; and 5 to 15 volume percent of the reinforcing layer; wherein the volume percent values are based on a total volume of the dielectric layer.

Aspect 2: The dielectric layer of Aspect 1, wherein the fluoropolymer comprises poly(chlorotrifluoroethylene), poly(chlorotrifluoroethylene-propylene), poly(ethylene-tetrafluoroethylene), poly(ethylene-chlorotrifluoroethylene), poly(hexafluoropropylene), poly(tetrafluoroethylene), poly(tetrafluoroethylene-ethylene-propylene), poly(tetrafluoroethylene-hexafluoropropylene), poly(tetrafluoroethylene-propylene), poly(tetrafluoroethylene-perfluoropropylene vinyl ether), a copolymer having a tetrafluoroethylene backbone with a fully fluorinated alkoxy side chain, polyvinylfluoride, polyvinylidene fluoride, poly(vinylidene fluoride-chlorotrifluoroethylene), perfluoropolyether, perfluorosulfonic acid, perfluoropolyoxetane, or a combination comprising at least one of the foregoing.

Aspect 3: The dielectric layer of any one or more of the preceding aspects, wherein the fluoropolymer comprises polytetrafluoroethylene.

Aspect 4: The dielectric layer of any one or more of the preceding aspects, wherein the dielectric layer comprises 18 to 30 volume percent of the plurality of boron nitride particles.

Aspect 5: The dielectric layer of any one or more of the preceding aspects, wherein the plurality of boron nitride particles comprises boron nitride platelets, preferably, hexagonal boron nitride platelets.

Aspect 6: The dielectric layer of any one or more of the preceding aspects, wherein the plurality of boron nitride particles has a boron nitride D₅₀ value of 5 to 40 micrometers.

Aspect 7: The dielectric layer of any one or more of the preceding aspects, wherein the dielectric layer comprises 1 to 10 volume percent of the plurality of titanium dioxide particles.

Aspect 8: The dielectric layer of any one or more of the preceding aspects, wherein the titanium dioxide comprises rutile titanium dioxide.

Aspect 9: The dielectric layer of any one or more of the preceding aspects, wherein the plurality of titanium dioxide particles comprises irregularly shaped particles, each independently having a plurality of flat surfaces.

Aspect 10: The dielectric layer of any one or more of the preceding aspects, wherein the titanium dioxide D₅₀ value is 1 to 40 micrometers, or 1 to 25 micrometers.

Aspect 11: The dielectric layer of any one or more of the preceding aspects, wherein the dielectric layer comprises 15 to 25 volume percent of the plurality of silica particles.

Aspect 12: The dielectric layer of any one or more of the preceding aspects, wherein the plurality of silica particles has a silica D₅₀ value of 5 to 15 micrometers.

Aspect 13: The dielectric layer of any one or more of the preceding aspects, wherein the silica comprises amorphous silica.

Aspect 14: The dielectric layer of any one or more of the preceding aspects, wherein one or more of the plurality of boron nitride particles, the plurality of titanium dioxide particles, and the plurality of silica particles comprises a surface treatment.

Aspect 15: The dielectric layer of any one or more of the preceding aspects, wherein the reinforcing layer comprises a woven fiberglass reinforcement or a non-woven fiberglass reinforcement.

Aspect 16: The dielectric layer of any one or more of the preceding aspects, wherein the dielectric layer has a z-direction thermal conductivity of 1 to 2 W/mK.

Aspect 17: A method of making a dielectric layer, for example, the dielectric layer of any one of the preceding aspects, comprising: impregnating the reinforcing layer with a mixture comprising a fluoropolymer, a plurality of boron nitride particles, a plurality of titanium dioxide particles, and a plurality of silica particles to form the dielectric layer.

Aspect 18: The method of Aspect 17, wherein the impregnating comprises dip coating or casting.

Aspect 19: A method of making the dielectric layer, for example, the dielectric layer of any one of Aspects 1 to 16, comprising: forming a mixture comprising a fluoropolymer, a plurality of boron nitride particles, a plurality of titanium dioxide particles, a plurality of silica particles, and a plurality of glass fibers; and forming the dielectric layer from the mixture.

Aspect 20: The method of Aspect 19, wherein the forming the dielectric layer comprises paste extruding and calendering.

Aspect 21: An article comprising the dielectric layer of any one of the preceding aspects.

Aspect 22: A multilayer circuit board comprising the dielectric layer of any one of the preceding aspects.

Aspect 23: The multilayer circuit board of Aspect 22, wherein the dielectric layer has a z-direction thermal conductivity of 1 to 2 W/mK.

The compositions, methods, and articles can alternatively comprise, consist of, or consist essentially of, any appropriate materials, steps, or components herein disclosed. The compositions, methods, and articles can additionally, or alternatively, be formulated so as to be devoid, or substantially free, of any materials (or species), steps, or components, that are otherwise not necessary to the achievement of the function or objectives of the compositions, methods, and articles.

The terms “a” and “an” do not denote a limitation of quantity, but rather denote the presence of at least one of the referenced item. The term “or” means “and/or” unless clearly indicated otherwise by context. Reference throughout the specification to “an aspect”, “an embodiment”, “another embodiment”, “some embodiments”, and so forth, means that a particular element (e.g., feature, structure, step, or characteristic) described in connection with the embodiment is included in at least one embodiment described herein, and may or may not be present in other embodiments. In addition, it is to be understood that the described elements may be combined in any suitable manner in the various embodiments. “Optional” or “optionally” means that the subsequently described event or circumstance may or may not occur, and that the description includes instances where the event occurs and instances where it does not. The term “combination” is inclusive of blends, mixtures, alloys, reaction products, and the like. Also, “combinations comprising at least one of the foregoing” means that the list is inclusive of each element individually, as well as combinations of two or more elements of the list, and combinations of at least one element of the list with like elements not named.

Unless specified to the contrary herein, all test standards are the most recent standard in effect as of the filing date of this application, or, if priority is claimed, the filing date of the earliest priority application in which the test standard appears.

The endpoints of all ranges directed to the same component or property are inclusive of the endpoints, are independently combinable, and include all intermediate points and ranges. For example, ranges of “up to 25 volume percent, or 5 to 20 volume percent” is inclusive of the endpoints and all intermediate values of the ranges of “5 to 25 volume percent,” such as 10 to 23 volume percent, etc.

Unless defined otherwise, technical and scientific terms used herein have the same meaning as is commonly understood by one of skill in the art to which this disclosure belongs.

All cited patents, patent applications, and other references are incorporated herein by reference in their entirety. However, if a term in the present application contradicts or conflicts with a term in the incorporated reference, the term from the present application takes precedence over the conflicting term from the incorporated reference.

While particular embodiments have been described, alternatives, modifications, variations, improvements, and substantial equivalents that are or may be presently unforeseen may arise to applicants or others skilled in the art. Accordingly, the appended claims as filed and as they may be amended are intended to embrace all such alternatives, modifications variations, improvements, and substantial equivalents.

What is claimed is:

1. A multilayer circuit board comprising:
a conductive layer; and a
dielectric layer; wherein the dielectric layer comprises
25 to 45 volume percent of a fluoropolymer, wherein the fluoropolymer comprises polytetrafluoroethylene;
15 to 35 volume percent of a plurality of boron nitride platelets;
1 to 32 volume percent of a plurality of titanium dioxide particles;
5 to 35 volume percent of a plurality of silica particles; and
5 to 15 volume percent of a fiberglass reinforcement;
wherein the volume percent values are based on a total volume of the dielectric layer;
wherein the dielectric layer has a z-direction thermal conductivity of 1 to 5 W/mK.

2. The multilayer circuit board of claim 1, wherein the dielectric layer has a permittivity of 2 to 6.5 as measured at a frequency of 10 gigahertz.

3. A dielectric layer comprising:
25 to 45 volume percent of a fluoropolymer, wherein the fluoropolymer comprises polytetrafluoroethylene;
15 to 30 volume percent of a plurality of boron nitride platelets having a boron nitride D₅₀ value of 5 to 40 micrometers;
5 to 10 volume percent of a plurality of titanium dioxide particles having a titanium dioxide D₅₀ value is 1 to 40 micrometers;
5 to 35 volume percent of a plurality of silica particles; and
5 to 15 volume percent of a fiberglass reinforcement;
wherein the volume percent values are based on a total volume of the dielectric layer;
wherein the dielectric layer has a z-direction thermal conductivity of 1 to 10 W/mK; and a permittivity of 2 to 6.5 as measured at a frequency of 10 gigahertz.

4. The dielectric layer of claim 3, wherein the dielectric layer comprises 15 to 30 volume percent of the plurality of boron nitride platelets.

5. The dielectric layer of claim 3, wherein the plurality of boron nitride platelets has a boron nitride D₅₀ value of 5 to 40 micrometers.

6. The dielectric layer of claim 3, wherein the dielectric layer comprises 5 to 10 volume percent of the plurality of titanium dioxide particles.

7. The dielectric layer of claim 3, wherein the titanium dioxide comprises rutile titanium dioxide.

8. The dielectric layer of claim 3, wherein the plurality of titanium dioxide particles comprises irregularly shaped particles, each independently having a plurality of flat surfaces.

9. The dielectric layer of claim 3, wherein the titanium dioxide D₅₀ value is 1 to 40 micrometers.

10. The dielectric layer of claim 3, wherein the dielectric layer comprises 15 to 25 volume percent of the plurality of silica particles.

11. The dielectric layer of claim 3, wherein the plurality of silica particles has a silica D₅₀ value of 5 to 15 micrometers.

12. The dielectric layer of claim 3, wherein the silica comprises amorphous silica.

13. The dielectric layer of claim 3, wherein one or more of the plurality of boron nitride particles, the plurality of titanium dioxide platelets, and the plurality of silica particles comprise a surface treatment.

14. The dielectric layer of claim 3, wherein the fiberglass reinforcement comprises a woven fiberglass reinforcement.

15. A method of making the dielectric layer of claim 3, comprising:
impregnating the fiberglass reinforcement with a mixture comprising the fluoropolymer, the plurality of boron nitride platelets, the plurality of titanium dioxide particles, and the plurality of silica particles to form the dielectric layer;
wherein the impregnating optionally comprises dip coating or casting.

16. A method of making the dielectric layer of claim 3, comprising:
forming a mixture comprising the fluoropolymer, the plurality of boron nitride platelets, the plurality of titanium dioxide particles, the plurality of silica particles, and a plurality of glass fibers; and
forming the dielectric layer from the mixture;
wherein the forming the dielectric layer optionally comprises paste extruding and calendering.

17. A multilayer circuit board comprising the dielectric layer of claim 3.

18. A dielectric layer comprising:
25 to 45 volume percent of a fluoropolymer comprising polytetrafluoroethylene;
20 to 25 volume percent of a plurality of boron nitride particles;
1 to 10 volume percent of a plurality of titanium dioxide particles;
10 to 30 volume percent of a plurality of silica particles; and
5 to 15 volume percent of a fibrous reinforcement;
wherein the volume percent values are based on a total volume of the dielectric layer; and
wherein the dielectric layer has a z-direction thermal conductivity of 1 to 5 W/mK; and a permittivity of 2 to 6.5 as measured at a frequency of 10 gigahertz.
